(19) United States
(12) Patent Application Publication
(10) Pub. No.: US 2025/0219020 A1
(43) Pub. Date: Jul. 3, 2025

(54) METHOD OF MANUFACTURING SEMICONDUCTOR PACKAGE BY USING CARRIER SUBSTRATE

(71) Applicant: Samsung Electronics Co., Ltd., Suwon-si (KR)

(72) Inventors: Junho CHOI, Suwon-si (KR); Jonghyeon CHANG, Suwon-si (KR); Daeeun HEO, Suwon-si (KR)

(73) Assignee: Samsung Electronics Co., Ltd., Suwon-si (KR)

(21) Appl. No.: 18/787,011

(22) Filed: Jul. 29, 2024

(30) Foreign Application Priority Data
Dec. 29, 2023 (KR) 10-2023-0197702

(51) Int. Cl. H01L 23/00; H01L 21/304; H01L 21/683; H01L 23/31; H01L 25/18; H10B 80/00

(52) U.S. Cl. CPC H01L 24/83; H01L 21/6835; H01L 23/3128; H01L 25/18; H10B 80/00; H01L 21/304; H01L 2221/68368; H01L 2221/68381; H01L 2224/83005; H01L 2224/83013; H01L 2224/83203; H01L 2224/83862; H01L 2924/35121

(57) ABSTRACT

A method of manufacturing a semiconductor package may use a carrier substrate and may include forming a first glue layer on a device substrate; forming a second glue layer on the first glue layer; coupling the device substrate to a carrier substrate by bonding the second glue layer to the carrier substrate; thinning the device substrate by grinding the device substrate; stacking first semiconductor chips on the device substrate after the thinning the device substrate; and separating the carrier substrate from the device substrate at an interface between the first glue layer and the second glue layer.

### CROSS-REFERENCE TO RELATED APPLICATION

This application is based on and claims ranking under 35 U.S.C. § 119 to Korean Patent Application No. 10-2023-0197702, filed on Dec. 29, 2023 in the Korean Intellectual Property office, the disclosure of which is incorporated by reference herein in its entirety.

### BACKGROUND

Inventive concepts relate to a method of manufacturing a semiconductor package, and more particularly, to a method of manufacturing a semiconductor package by using a carrier substrate.

Recently, as the degree of integration of semiconductor devices has increased and the performance of periphery devices has increased, a structure, in which chips are stacked vertically rather than horizontally, has been adopted. In the case of a vertical stacking structure, when a method of wire bonding is used, the package structure and the process may be complicated. Accordingly, a through silicon via (TSV), which simplifies the package structure while reducing a transmission path, is applied. In addition, a carrier wafer is used to stably proceed with the subsequent processes on the device wafer including the TSV. For reference, a process of temporarily coupling and separating a carrier wafer to and from a device wafer is called a wafer supporting system (WSS) process.

### SUMMARY

Inventive concepts provide a method of manufacturing a semiconductor package by using a carrier substrate, in which process stability is maintained and accordingly, a semiconductor package with improved reliability may be manufactured.

In addition, the issues to be solved by technical ideas of inventive concepts are not limited to those mentioned above, and other issues may be clearly understood by those of ordinary skill in the art from the following descriptions.

According to an embodiment of inventive concepts, a method of manufacturing a semiconductor package may use a carrier substrate. The method may include forming a first glue layer on a device substrate; forming a second glue layer on the first glue layer; coupling the device substrate to a carrier substrate by bonding the second glue layer to the carrier substrate; thinning the device substrate by grinding the device substrate; stacking first semiconductor chips on the device substrate after the thinning the device substrate; and separating the carrier substrate from the device substrate at an interface between the first glue layer and the second glue layer.

According to an embodiment of inventive concepts, a method of manufacturing a semiconductor package may use a carrier substrate. The method may include forming a first glue layer on a device substrate; curing the first glue layer at a first temperature; forming a second glue layer on the first glue layer; coupling the device substrate to the carrier substrate by bonding a carrier substrate to the second glue layer; curing the second glue layer at a second temperature higher than the first temperature; thinning the device substrate by grinding the device substrate; stacking a plurality of first semiconductor chips on the device substrate; sealing the plurality of first semiconductor chips on the device substrate with a sealing material; and separating the carrier substrate from the device substrate at an interface between the first glue layer and the second glue layer. The first glue layer and the second glue layer may include a same material.

According to an embodiment of inventive concepts, a method of manufacturing a semiconductor package may use a carrier substrate. The method may include forming a first glue layer and a second glue layer on a device substrate, the first glue layer and the second glue layer including a same material and being cured at different temperatures to form an interface between the first glue layer and the second glue layer; coupling the device substrate to the carrier substrate by bonding the carrier substrate to the second glue layer; thinning the device substrate by grinding the device substrate; stacking first semiconductor chips on the device substrate; and separating the carrier substrate from the device substrate at the interface between the first glue layer and the second glue layer.

### BRIEF DESCRIPTION OF THE DRAWINGS

Embodiments will be more clearly understood from the following detailed description taken in conjunction with the accompanying drawings in which:

FIGS. 1A and 1B are cross-sectional views schematically illustrating a method of manufacturing a semiconductor package by using a carrier substrate, according to embodiments, and a method of manufacturing a semiconductor package by using a carrier substrate, according to a comparison example, respectively;

FIGS. 2A to 2L are cross-sectional views illustrating in detail a method of manufacturing a semiconductor package by using the carrier substrate, according to the embodiment of FIG. 1A;

FIGS. 3A to 3C are a cross-sectional view and graphs for explaining issues in a method of manufacturing a semiconductor package by using the carrier substrate, according to the comparison example of FIG. 1B, respectively;

FIGS. 4A and 4B are conceptual diagrams for explaining a process of separating the carrier substrate in the method of manufacturing a semiconductor package by using the carrier substrate, according to the embodiment of FIGS. 1A and 1n the method of manufacturing a semiconductor package by using the carrier substrate, according to the comparison example of FIG. 1B, respectively;

FIG. 5 illustrates graphs amounts of change in peel strength, in the method of manufacturing a semiconductor package by using the carrier substrate, according to the embodiment of FIG. 1A, and in the method of manufacturing a semiconductor package by using the carrier substrate, according to the comparison example of FIG. 1B; and

FIGS. 6A to 6D are cross-sectional views illustrating a method of manufacturing a semiconductor package by using a carrier substrate, according to embodiments.

### DETAILED DESCRIPTION OF THE EMBODIMENTS

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. The notion that elements are “substantially the same” may indicate that the element may be completely the same and may also indicate that the elements may be determined to be the same in consideration of errors or deviations occurring during a process.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Hereinafter, embodiments of inventive concepts will be described in detail with reference to the accompanying drawings. Identical reference numerals are used for the same constituent elements in the drawings, and duplicate descriptions thereof are omitted.

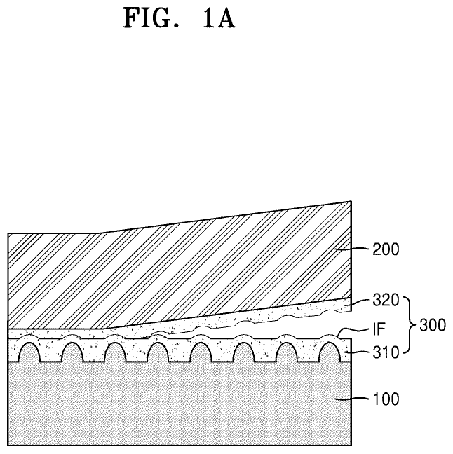

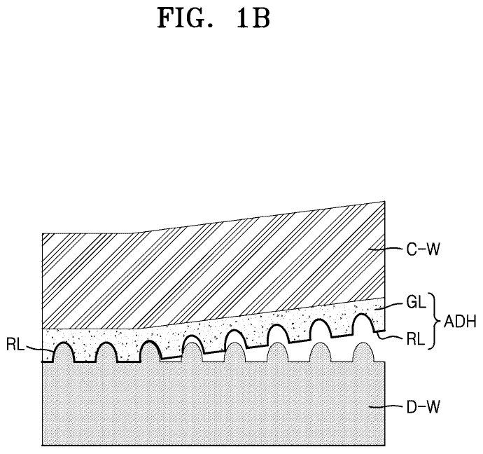

FIGS. 1A and 1B are cross-sectional views schematically illustrating a method of manufacturing a semiconductor package by using a carrier substrate, according to an embodiment, and a method of manufacturing a semiconductor package by using a carrier substrate, according to a comparison example, respectively.

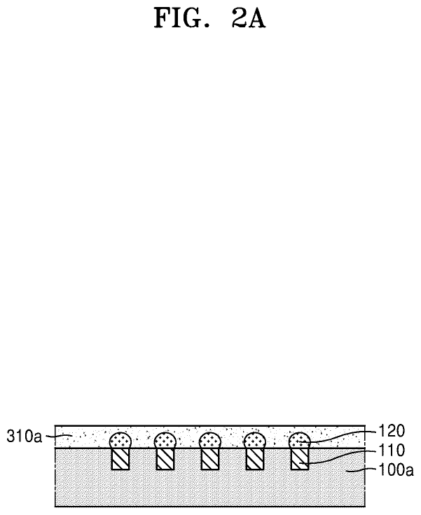

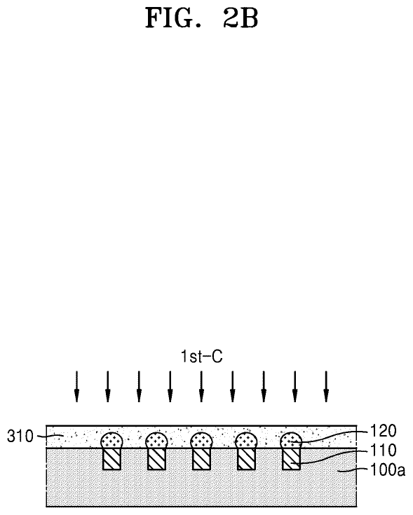

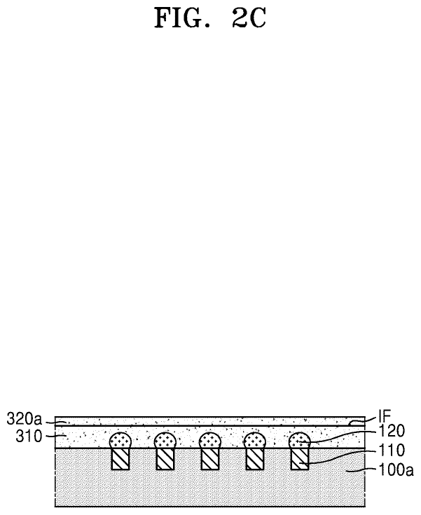

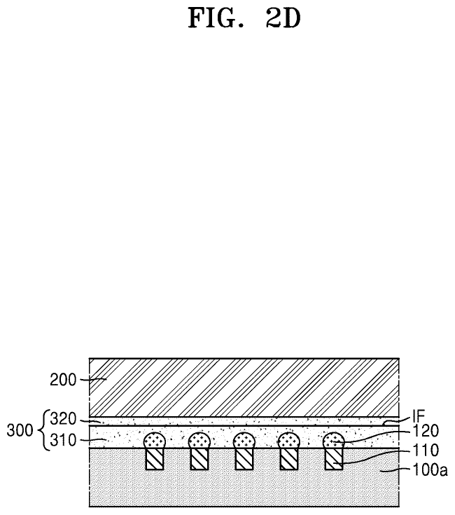

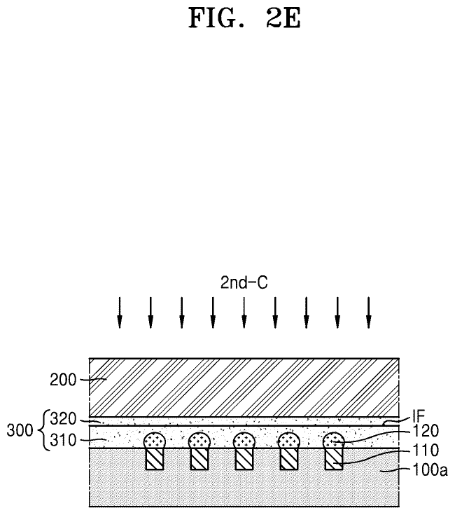

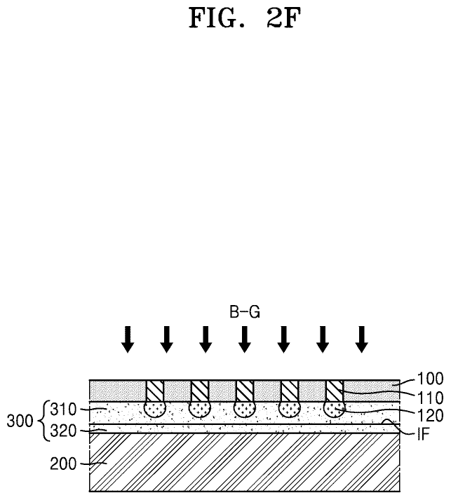

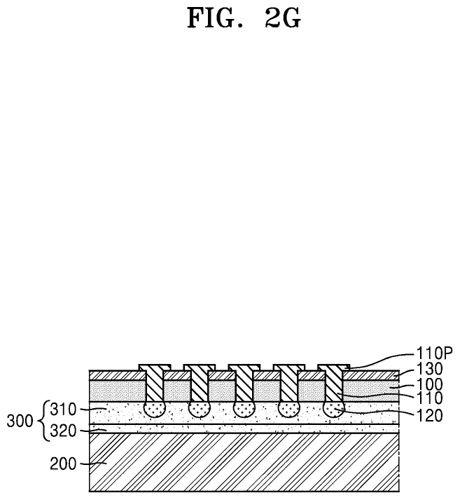

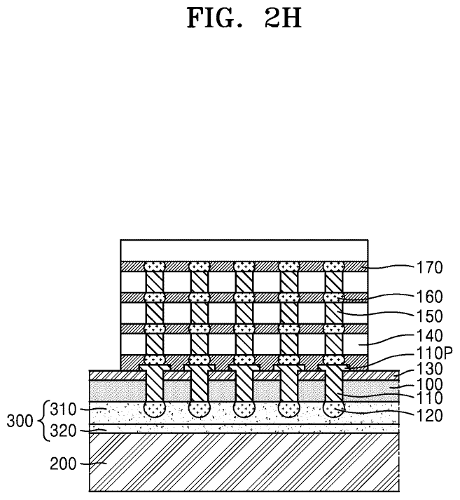

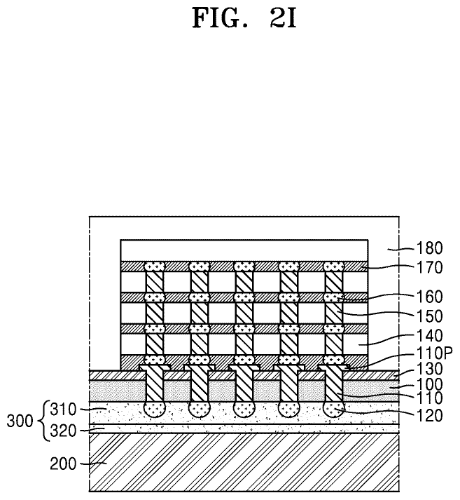

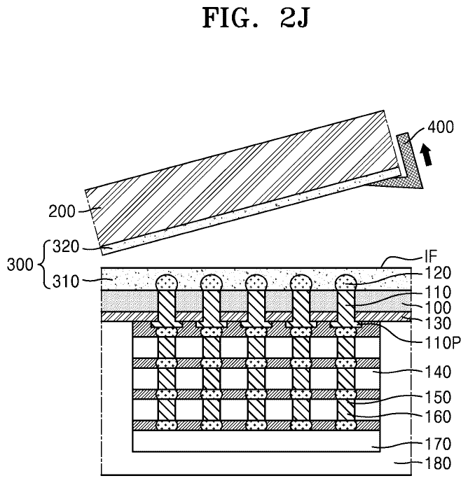

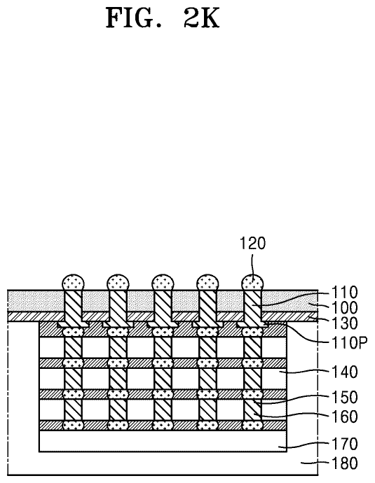

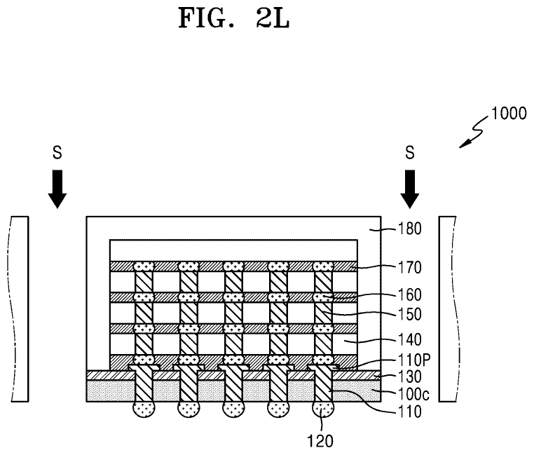

Referring to FIG. 1A, the method of manufacturing a semiconductor package by using a carrier substrate, according to the embodiment (hereinafter, simply referred to as a ‘method of manufacturing a semiconductor package’) may bond a carrier substrate 200 to a device substrate 100 by using two glue layers 310 and 320. In the method of manufacturing a semiconductor package, the device substrate 100 including through silicon via (TSV) (refer to 110 in FIG. 2A) formed therein may be combined with the carrier substrate 200 via an adhesive layer 300 before a thinning process of thinning the device substrate 100. For reference, the bonding between the device substrate 100 and the carrier substrate 200 via the adhesive layer 300 may be separated again in a subsequent process, and thus, the bonding may be called a temporary bonding or a temporary wafer bonding.

The device substrate 100 may include, for example, silicon. Of course, the material of the device substrate 100 is not limited thereto. The device substrate 100 may be described in more detail with reference to FIG. 2A. The carrier substrate 200 may include various materials. For example, the carrier substrate 200 may include silicon, glass, ceramic, organic material, or plastic. However, the material of the carrier substrate 200 is not limited thereto.

Both the device substrate 100 and the carrier substrate 200 may have a circular flat plate shape. Accordingly, in some embodiments, the device substrate 100 and the carrier substrate 200 may be referred to as a device wafer and a carrier wafer, respectively. The carrier substrate 200 may have a diameter greater than that of the device substrate 100. In addition, the carrier substrate 200 may have a thickness greater than that of the device substrate 100. However, in some embodiments, the carrier substrate 200 may have substantially the same diameter as the device substrate 100. Also, before the device substrate 100 becomes thin, the carrier substrate 200 may have substantially the same thickness as the device substrate 100.

In FIG. 1A, protrusion portions on an upper surface of the device substrate 100 may correspond to, for example, an external connection terminal (refer to 120 in FIG. 2A). The device substrate 100, the TSV 110, and the external connection terminal 120 are described in more detail with reference to FIG. 2A.

In the method of manufacturing a semiconductor package according to the present embodiment, to couple the device substrate 100 and the carrier substrate 200, an adhesive layer 300 including a first glue layer 310 and a second glue layer 320 may be used. In addition, the first glue layer 310 and the second glue layer 320 may include substantially the same material, but after they are cured at different temperatures, an interface IF may be between the first glue layer 310 and the second glue layer 320. Furthermore, when the first glue layer 310 and the second glue layer 320 combine the carrier substrate 200 with the device substrate 100 at the initial state, the first glue layer 310 and the second glue layer 320 may provide high bonding force, and in addition, in a subsequent debonding process of debonding the carrier substrate 200 from the device substrate 100, the interface IF between the first glue layer 310 and the second glue layer 320 may facilitate the debonding of the carrier substrate 200. For example, as illustrated in FIG. 1A, in the debonding process between the device substrate 100 and the carrier substrate 200, debonding may occur at the interface IF having a relatively low adhesive force. Forming, curing, and coupling of the first glue layer 310 and the second glue layer 320, debonding of the carrier substrate 200 via the interface IF, or the like are described in more detail with reference to FIGS. 2A through 2L.

Referring to FIG. 1B, on the other hand, in the case of the method of manufacturing a semiconductor package according to the comparison example, a carrier wafer C-W may be bonded to a device wafer D-W by using an adhesive layer ADH including a release layer RL and a glue layer GL. Because the device wafer D-W and the carrier wafer C-W are substantially the same as the device substrate 100 and the carrier substrate 200, respectively, detailed descriptions thereof are omitted.

The adhesive layer ADH may include the release layer RL and the glue layer GL. The release layer RL may be directly formed on the device wafer D-W. The release layer RL may include, for example, a thermosetting resin, such as an epoxy resin and a silicone resin. In addition, the release layer RL may also include any one of a silsesquioxane-based resin and a thermoplastic resin. The release layer RL may be formed to have a thin thickness of about 100 nm to about 500 nm. The release layer RL may be formed in a shape of an upper surface of the device wafer D-W, for example, in a thinly coated shape of the upper surface of the device wafer D-W and an external connection terminal.

On the other hand, the release layer RL may have a double layer structure of a precursor layer and a chemical vapor deposition (CVD) layer. For example, the precursor may be adsorbed and coated on the device wafer D-W, then, a reaction gas may be supplied to cause chemical substitution with the adsorbed precursor, and thus, the release layer RL having a double layer structure, in which the precursor layer is on a lower portion and the CVD layer is on an upper portion. In addition, in some embodiments, a process of curing the release layer RL may be included. For example, the curing of the release layer RL may include providing oxygen radicals to react with the upper portion of the release layer.

The glue layer GL may include a vinyl-functionalized polysiloxane oligomer resin, an Si—H functional polysiloxane oligomer resin, a polysiloxane-based material, an acrylic-based material, etc. In addition, the glue layer GL may selectively include a catalyst, an inhibitor, a curing agent, etc. The glue layer GL may include at least one of, for example, a non-conductive film (NCF), an anisotropic conductive film (ACF), an ultraviolet (UV) film, an instantaneous adhesive, a thermosetting adhesive, a laser curable adhesive, an ultrasonic curable adhesive, and a non-conductive paste (NCP).

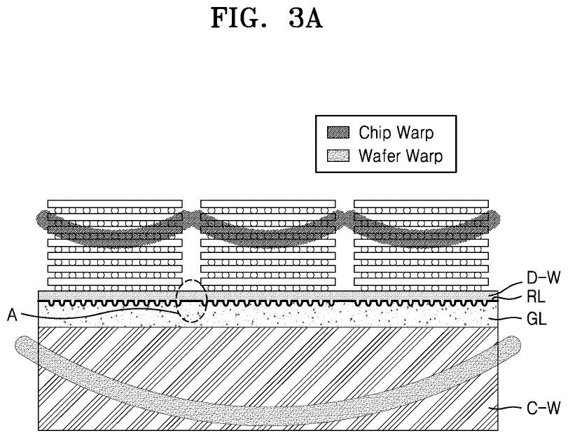

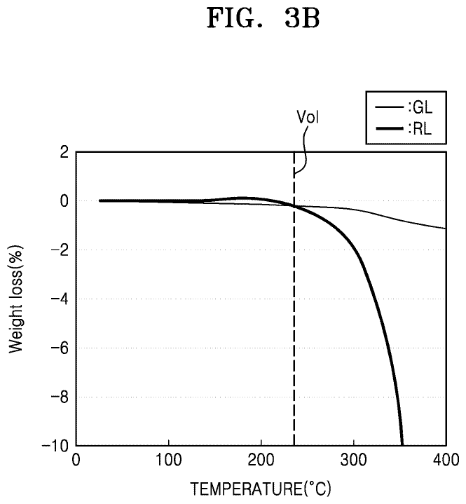

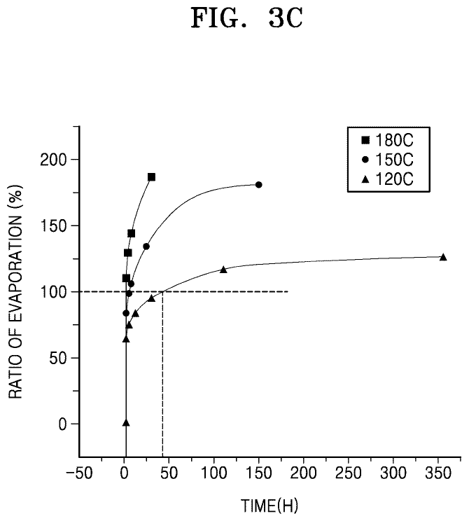

As may be understood from FIG. 1B, in the case of the method of manufacturing a semiconductor package according to the comparison example, in the process of debonding the carrier wafer C-W from the device wafer D-W, debonding may occur at the interface between the release layer RL and the device wafer D-W. However, in the case of the method of manufacturing a semiconductor package according to the comparison example, because the adhesive layer ADH includes the release layer RL, there may be issues, such as initial low peel strength, swelling and cracking due to outgassing during an assembly process, and a crack occurrence in the device wafer D-W or the carrier wafer C-W during the debonding process of the carrier wafer C-W due to excessive increase in the peel strength after the assembly process. Here, peel strength may mean adhesion strength. The issues of the method of manufacturing a semiconductor package according to the comparison example are described in more detail with reference to FIGS. 3A through 3C, 4B, and 5.

On the other hand, in the case of the method of manufacturing the semiconductor package according to the present embodiment, the adhesive layer 300 may include only the first glue layer 310 and the second glue layer 320, and in addition, an interface may be maintained between the first glue layer 310 and the second glue layer 320 by curing at different temperatures, thereby solving all of the issues described above. For example, because the first glue layer 310 and the second glue layer 320 are coupled with a relatively high peel strength, the initial low peel strength issue may be solved. In addition, in the case of the first glue layer 310 and the second glue layer 320, because the outgassing phenomenon may hardly occur, the issue caused by the outgassing phenomenon of the release layer RL may be solved. Furthermore, because the peel strength does not increase significantly even after the assembly process, the issue of crack occurrence in the device substrate 100 or the carrier substrate 200 during the debonding process of the carrier substrate 200 may be solved. As a result, the method of manufacturing a semiconductor package according to the present embodiment may solve all of the issues described above, and may allow a reliable semiconductor package to be manufactured.

On the other hand, the manufacturing method of a semiconductor package according to the present embodiment may be basically based on a water supporting system (WSS) process. For reference, in the WSS process, due to the recent introduction of high bandwidth memory (HBM) packages, thermal compression (TC) bonding and 2.5-dimensional (2.5D) package structures are rapidly increasing. In this case, the 2.5D package structure may be a relative concept for a three-dimensional (3D) package structure in which all semiconductor chips are vertically stacked without interposers. The 2.5D package structure may increase signal transmission between chips exponentially and rapidly. In general, the HBM package is manufactured by each memory company in the 3D package structure, and the HBM package may combined with a graphics processing unit (GPU) in the 2.5D package structure.

With the recent development of artificial intelligence (AI), the number of neutral processing units (NPU)/GPUs/central processing units (CPU)/application processors (AP) requiring the 2.5D and/or 3D packages as well as the demand for the HBM packages is inevitably increasing. In particular, in the case of the HBM packages, the TSV process may be essential. The TSV process may be a process in which wirings penetrating vertically up and down are manufactured. More detailed descriptions of the TSV are given with reference to FIG. 2A.

On the other hand, to perform the TSV process on a device wafer and to perform the assembly process of stacking chips on the device wafer after the TSV process, the process of temporarily attaching a carrier wafer to the device wafer and debonding the carrier wafer after the assembly process is performed. In this manner, the processes of attaching the carrier wafer to the device wafer, performing subsequent processes on the device wafer, and thereafter, debonding the carrier wafer, may be called the WSS process.

In general, when the device wafer is thinned by using the back grinding process, a warpage may occur on the device wafer. Accordingly, after the back grinding process, the device wafer may be taped to a ring frame to proceed with the subsequent processes. However, as illustrated in FIG. 2A, when the TSV process is performed on the device wafer, an external connection terminal, or bump, may be placed on a front surface of the device wafer, and thus, the device wafer may not be attached to the ring frame. Due to this reason, the WSS process may be performed for the device wafer on which the TSV process has been performed.

In the WSS process, by attaching the front surface of the device wafer including bumps on the carrier wafer with a temporary adhesive, and grinding the rear surface of the device wafer, the wafer may be thinned. Because the device wafer is coupled to the carrier wafer, the thinned device wafer may not bend. In addition, because the carrier wafer also has a wafer shape, subsequent processes may be performed as is in semiconductor equipment. Thus, an assembly process of stacking memory chips on the thinned device wafer may be performed. After the assembly process, by separating the carrier wafer from the device wafer, and performing a singulation process on the ring frame, the semiconductor packages may be individualized. Each of the individualized semiconductor packages may correspond to, for example, the HBM package.

As a result, the WSS may be referred to as a system, in which the carrier wafer is coupled before the back grinding process and subsequent processes are handled to be performed on the thinned device wafer by using the back grinding process, and may be referred to as a system in which the carrier wafer is substantially coupled to the device wafer. In addition, the WSS process may include a bonding process of attaching the carrier wafer to the device wafer, and a debonding process of separating the carrier wafer again after completing the subsequent processes on the device wafer. On the other hand, the debonding process may include a process of cleaning with a cleaning solution so that no adhesive layer component remains on wafers.

In addition, conditions to be considered in the bonding process of the WSS process may be a uniform overall thickness of the coupled wafers, no voids at the junction, good alignment between the two wafers, no adhesive contamination at the edge of the wafer, and less bending of the device wafer. In addition, considerations to be considered in the debonding process of the WSS process may be that when separating the carrier wafer, there should be no damage, such as chipping and cracking, in each of the two wafers, no adhesive layer residue left, and no occurrence of bump deformation of the device wafer.

The relatively difficult and important process in the WSS process may be the debonding process. Thus, various debonding methods are being proposed and developed, and temporary adhesives suitable for each method are also being developed. For example, a thermal method, a peel-off method after laser irradiation, a chemical dissolution method, a chemical cleaning method after mechanical lift-off, or the like may be applied to the debonding process.

FIGS. 2A through 2L are cross-sectional views illustrating in detail a method of manufacturing a semiconductor package by using the carrier substrate 200, according to the embodiment in FIG. 1A.

Referring to FIG. 2A, in the method of manufacturing a semiconductor package according to the present embodiment, firstly, a first glue layer 310a may be formed on a device substrate 100a. The device substrate 100a may include a semiconductor wafer, such as a silicon wafer, but is not limited thereto. For example, the device substrate 100a may include a compound semiconductor, such as a silicon-on-insulator (SOI), silicon-germanium, silicon-carbide, and gallium-arsenide. However, the material of the device substrate 100a is not limited thereto. The device substrate 100 may have a circular flat plate shape. Accordingly, the device substrate 100a may be referred to as a device wafer.

An active region may be formed in an upper portion of the device substrate 100a. Accordingly, in FIG. 1A, the upper surface of the device substrate 100a may correspond to a front surface, which is an active surface, and the lower surface thereof may correspond to a rear surface, which is an inactive surface. In addition, a plurality of TSVs 110 penetrating the active region may be formed inside the device substrate 100a. Integrated circuits may be formed in the active region. Integrated circuits may include, for example, memory devices, such as dynamic random access memory (RAM) (DRAM), static RAM (SRAM), and flash memory. In addition, integrated circuits may include logic devices constituting a central processing unit (CPU), a digital signal processor (DSP), a processor in which the CPU and the DSP are coupled, an application specific integrated circuit (ASIC), a micro-electro-mechanical system (MEMS) device, a photoelectronic device, or the like, and a combination of logic devices. The memory devices or logic devices of the device substrate 100a may be separated into semiconductor chip shape by performing an individualization process on the device substrate 100 in a subsequent process. For example, in the method of manufacturing a semiconductor package according to the present embodiment, the device substrate 100a may include multiple semiconductor chips, and may be separated into an individual semiconductor chip by performing an individualization process. In addition, each of the semiconductor chips of the device substrate 100a may include logic devices. For example, each of the semiconductor chips of the device substrate 100a may include a buffer chip or a control chip.

The TSV 110 may be formed by forming a via hole having a certain depth from an upper surface to a lower surface of the device substrate 100a, and then by filling the via hole with conductive materials. For example, the via hole may be formed by using a deep reactive ion etch (DRIE) process. The TSV 110 may have a columnar shape, and may include a barrier layer on a surface and a buried conductive layer therein. The barrier layer may include at least one material of Ti, TiN, Ta, TaN, Ru, Co, Mn, WN, Ni, and NiB. The buried conductive layer may include at least one material of a Cu alloy, such as Cu, CuSn, CuMg, CuNi, CuZn, CuPd, CuAu, CuRe, and CuW, W, a W alloy, Ag, Au, Al, In, Ni, Ru, and Co. On the other hand, a via insulating layer may be arranged between the TSV 110 and the device substrate 100a. The via insulating layer may include an oxide layer, a nitride layer, a carbide layer, polymer, or a combination thereof.

After the TSV 110 is formed, a pad may be formed on an exposed surface of the TSV 110 on the upper surface of the device substrate 100a. The pad may include at least one of Al, Cu, Ni, W, Pt, and Au. On the on the other hand, a protective layer may be formed on the upper surface of the device substrate 100a, and the TSV 110 or the pad may penetrate the protective insulating layer. In some embodiments, a distribution layer or a redistribution layer may be formed on an upper portion of the device substrate 100a. In this case, a separate pad may be formed on the distribution layer or the redistribution layer. In addition, the TSV 110 may be connected to the distribution of the distribution layer or the redistribution layer, and may be connected to the pad via the distribution of the distribution layer or the redistribution layer. On the other hand, in some embodiments, the TSV 110 may also be formed in a structure to penetrate the distribution layer.

The external connection terminal 120 may be arranged on the pad. The external connection terminal 120 may include a pillar and a solder layer. In some embodiments, the external connection terminal 120 may also include only a solder layer. The pillar may include, for example, Ni, Cu, Pd, Pt, Au, or a combination thereof. According to the embodiment, a diffusion barrier layer and/or an adhesive layer may be formed between the pillar and the solder layer. The solder layer may be arranged on the pillar, and may have a spherical or ball shape. The solder layer may include, for example, at least one of tin (Sn), indium (In), bismuth (Bi), antimony (Sb), copper (Cu), silver (Ag), zinc (Zn), lead (Pb), and/or an alloy thereof. For example, the solder layer may include at least one of Sn, Pb, Sn—Pb, Sn—Ag, Sn—Au, Sn—Cu, Sn—Bi, Sn—Ag—Cu, Sn—Ag—Bi, Sn—Cu—Zn, Sn—Cu—Zn, Sn—Cu—Zn, Sn—Bi—Zn, Sn—Bi—Zn, etc. On the other hand, according to the embodiment, an intermediate layer such as an intermetallic compound (IMC) may be formed on a contact interface between the solder layer and the pillar.

The first glue layer 310a may be formed by doping liquid glue on the device substrate 100a by using a spin coating method. As illustrated in FIG. 2A, the first glue layer 310a may be formed to completely cover the external connection terminal 120. For example, the first glue layer 310a may be formed to have a thickness of about 50 μm or more. However, the thickness of the first glue layer 310a is not limited thereto.

The first glue layer 310a may include a vinyl-functionalized polysiloxane oligomer resin, an Si—H functional polysiloxane oligomer resin, a polysiloxane-based material, an acrylic-based material, etc. In addition, the first glue layer 310a may selectively include a catalyst, an inhibitor, a curing agent, etc. The first glue layer 310a may include at least one of, for example, non-conductive film (NCF), anisotropic conductive film (ACF), ultraviolet (UV) film, instantaneous adhesive, thermosetting adhesive, laser curable adhesive, ultrasonic curable adhesive, and non-conductive paste (NCP). However, the material of the first glue layer 310a is not limited thereto. In the manufacturing method of a semiconductor package according to the present embodiment, the first glue layer 310a may include, for example, a curing agent, and may be hardened by curing at a certain temperature.

Referring to FIG. 2B, after the first glue layer 310a is formed, a first curing 1st-C may be performed. In the method of manufacturing a semiconductor package according to the present embodiment, the temperature of the first curing 1st-C may be about 160° C. to about 180° C. However, the temperature of the first curing 1st-C is not limited thereto. The first glue layer 310 hardened by using the first curing 1st-C may be formed.

Referring to FIG. 2C, after the first curing 1st-C is performed, a second glue layer 320a may be formed on the first glue layer 310. The second glue layer 320a may also be formed by doping liquid glue on the first glue layer 310 by using a spin coating method. As illustrated in FIG. 2C, the second glue layer 320a may be formed thinner than the first glue layer 310. For example, the second glue layer 320a may be formed thinner than the first glue layer 310 at a thickness of about 50 μm or less. However, the thickness of the second glue layer 320a is not limited thereto.

On the on the other hand, the second glue layer 320a may include substantially the same material as the first glue layer 310. For example, in the method of manufacturing a semiconductor package according to the present embodiment, the second glue layer 320a, like the first glue layer 310a, may include a curing agent, and may be hardened by curing at a certain temperature. However, because the second glue layer 320a has not been cured, as illustrated in FIG. 2C, the interface IF may be formed between the first glue layer 310 in a hardened state and the second glue layer 320a in a liquid state.

Referring to FIG. 2D, after the second glue layer 320a is formed, the carrier substrate 200 may be adhered to the second glue layer 320a to couple the carrier substrate 200 to the device substrate 100a. The carrier substrate 200 may include silicon, glass, ceramic, organic material, or plastic. However, the material of the carrier substrate 200 is not limited thereto. The carrier substrate 200 may have a circular flat plate shape. Accordingly, the carrier substrate 200 may also be referred to as a carrier wafer.

The carrier substrate 200 may have a greater diameter than the device substrate 100a. In addition, the carrier substrate 200 may have a greater thickness than the device substrate 100a. However, in some embodiments, the carrier substrate 200 may have substantially the same diameter as the device substrate 100a. In addition, before the device substrate 100a is thinned, the carrier substrate 200 may also have substantially the same thickness as the device substrate 100a. Hereinafter, a structure, in which the carrier substrate 200 is coupled to the device substrate 100a, may be referred to as a ‘coupled structure’. In this case, the coupled structure may correspond to the WSS described above.

Referring to FIG. 2E, after the coupled structure is formed, second curing 2nd-C may be performed. In the method of manufacturing a semiconductor package according to the present embodiment, the temperature of the first curing 1st-C and the temperature of the second curing 2nd-C may be different from each other. For example, the temperature of the second curing 2nd-C may be higher than that of the first curing 1st-C. The temperature of the second curing 2nd-C may be about 190° C. to about 220° C. However, the temperature of the second curing 2nd-C is not limited thereto. The second glue layer 320 may be formed by hardening by using the second curing 2nd-C. On the other hand, as the first glue layer 310 and the second glue layer 320 are hardened at different curing temperatures, an interface between the first glue layer 310 and the second glue layer 320 may be maintained even after the second curing 2nd-C.

Referring to FIG. 2F, after the second curing 2nd-C, the device substrate 100a may be thinned by using a thinning process. The coupled structure may be flipped so that the carrier substrate 200 is at the lower portion and the device substrate 100 is at the upper portion. The process of flipping the coupled structure may correspond to a process of actually seating the coupled structure on a substrate chuck of a back grinding B-G process. For example, an uncoupled surface of the carrier substrate 200 may be mounted on an upper surface of the substrate chuck. Thereafter, the device substrate 100 may be thinned by removing a rear surface portion of the device substrate 100a, that is, a portion of an inactive layer portion, by using a back grinding B-G process.

As can be seen from FIG. 2F, an upper surface of the TSV 110 may be exposed on an upper surface of the device substrate 100 by using the back grinding B-G process. On the other hand, as the coupled structure is flipped upside down, the positions of the upper and lower surfaces in FIG. 2F and previous diagrams may be exchanged with each other. For example, in FIG. 2F, the upper surface of the device substrate 100 may correspond to the rear surface which is an inactive surface.

Referring to FIG. 2G, after the thinning process, a rear surface protection layer 130 may be formed on the upper surface of the device substrate 100. The rear surface protection layer 130 may include a dielectric layer such as a silicon oxide layer, a silicon nitride layer, or a silicon oxynitride layer. In addition, the rear surface protection layer 130 may be formed in a multilayer structure such as silicon oxide layer/silicon nitride layer/silicon oxide layer.

On the other hand, a rear surface pad 110p may be formed on the upper surface of the TSV 110. The rear surface pad 110p may be formed in a structure to penetrate the rear surface protection layer 130. In some embodiments, the TSV 110 may penetrate the rear surface protection layer 130, and the rear surface pad 110p may be formed on the upper surface of the TSV 110 and the rear surface protection layer 130. The rear surface pad 110p may include substantially the same material as the TSV. Alternatively, according to the embodiment, the rear surface pad 110p may include a conductive material different from a material of the TSV.

Referring to FIG. 2H, thereafter, an assembly process may be performed on the device substrate 100. In this case, the assembly process may mean a process of stacking chips on each of the chips of the device substrate 100. Hereinafter, the chip of the device substrate 100 may be referred to as a ‘first semiconductor chip (refer to 100c in FIG. 2L)’ and chips stacked on the first semiconductor chip 100c may be referred to as ‘second semiconductor chips 140’. For reference, the device substrate 100 may include a plurality of first semiconductor chips 100c. In addition, a plurality of second semiconductor chips 140 may be stacked on each of the first semiconductor chips 100c. For example, in the method of manufacturing a semiconductor package according to the present embodiment, the first semiconductor chip 100c and the plurality of second semiconductor chips 140 on the first semiconductor chip 100c may constitute an HBM package.

To briefly describe the HBM package, the HBM package may include the first semiconductor chip 100c, the plurality of second semiconductor chips 140, and a sealing material (refer to 180 in FIG. 2I). The first semiconductor chip 100c may include, for example, a buffer chip or a control chip. In addition, each of the second semiconductor chips 140 may include a memory chip, for example, a DRAM chip. The first semiconductor chip 100c, which is a buffer chip, may be arranged at the lowermost portion of the HBM package, integrate signals of the second semiconductor chips 140 to transmit them to the outside, and in addition, transmit signals and power from the outside to the second semiconductor chips 140.

As illustrated in FIG. 2H, the first semiconductor chip 100c and the second semiconductor chips 140 may include TSVs 110 and 150. However, the uppermost second semiconductor chip 140 among the second semiconductor chips 140 may not include the TSV. In the method of manufacturing a semiconductor package according to the present embodiment, four second semiconductor chips 140 are stacked on the first semiconductor chip 100c, but the number of second semiconductor chips 140 is not limited thereto. For example, two, three, or five or more second semiconductor chips 140 may be stacked on the first semiconductor chip 100c. On the other hand, the external connection terminal 120 may be arranged on a lower surface of the first semiconductor chip 100c. In addition, a bump 160 and a chip adhesive layer 170 may be arranged between the first semiconductor chip 100c and the second semiconductor chip 140, and between the second semiconductor chips 140 adjacent to each other. The sealing material 180 may cover and seal the second semiconductor chip 140 on the first semiconductor chip 100c. The sealing material 180 is described in more detail with reference to FIG. 2I.

In the assembly process, the second semiconductor chip 140 may be stacked on the first semiconductor chip 100c or the lower second semiconductor chip 140 by using the bump 160 and the chip adhesive layer 170. In the process of stacking the second semiconductor chip 140, the second semiconductor chip 140 may be stacked by using a thermal compression bonding (TCB) method. In addition, in the TCB method, the chip adhesive layer 170 may include, for example, the NCF.

Referring to FIG. 2I, after the second semiconductor chips 140 are stacked on the first semiconductor chip 100c, the second semiconductor chips 140 on the device substrate 100 may be sealed with the sealing material 180. In some embodiments, a process of sealing with the sealing material 180 may also be included in the assembly process.

The sealing material 180 may cover and seal the second semiconductor chips 140 and the chip adhesive layer 170 on the first semiconductor chip 100c. The sealing material 180 may seal the second semiconductor chips 140 to protect the second semiconductor chips 140 from external physical and chemical damage. The sealing material 180 may include, for example, epoxy mold compound (EMC). However, the sealing material 180 is not limited thereto, and may include various materials, such as epoxy-based materials, thermosetting materials, thermoplastic materials, and UV curable materials. In addition, the sealing material 180 may include resin, and may contain a filler.

The sealing material 180 may seal all of the second semiconductor chips 140 on the device substrate 100. In other words, the sealing process using the sealing material 180 may be performed on a wafer level. In addition, as illustrated in FIG. 2I, the sealing material 180 may cover an upper surface of the second semiconductor chip 140 arranged at the uppermost portion. However, the sealing material 180 is not limited thereto, and may also not cover the upper surface of the uppermost second semiconductor chip 140. In other words, the upper surface of the uppermost second semiconductor chip 140 may be exposed on the sealing material 180.

Referring to FIGS. 2J and 2K, after the sealing material 180 is formed, the carrier substrate 200 may be separated from the device substrate 100. A method of separating the carrier substrate 200 may use, for example, a chemical cleaning method, after a mechanical lift-off process. However, the method of separating the carrier substrate 200 is not limited thereto. For example, a thermal method, a peel-off method after laser irradiation, a chemical dissolution method, or the like may be used for the method of separating the carrier substrate 200.

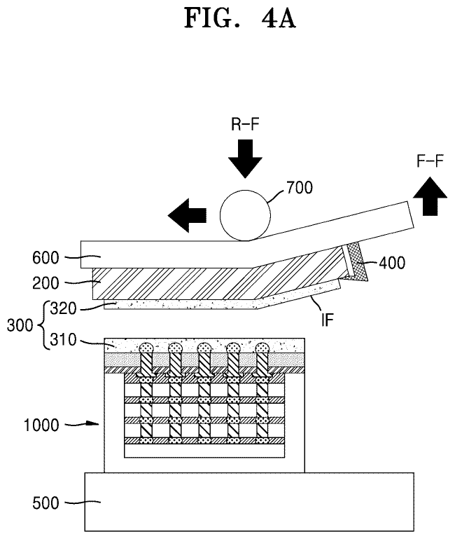

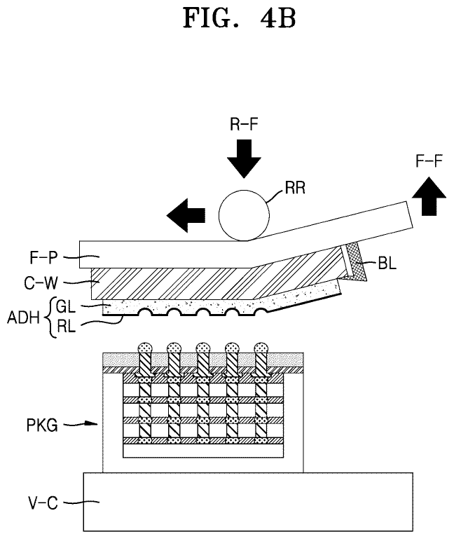

FIG. 2J illustrates a process of mechanical lifting-off of the carrier substrate 200 by using a blade 400. Although not illustrated, the device substrate 100, the second semiconductor chips 140, and the sealing material 180 may be fixed to a vacuum chuck (refer to 500 in FIG. 4A).

FIG. 2K illustrates a state in which the first glue layer 310 is removed from the device substrate 100 after the device substrate 100 is cleaned by using a cleaning liquid. By removing the first glue layer 310, the external connection terminal 120 may appear as protruding on a front surface of the device substrate 100.

Referring to FIG. 2L, a plurality of semiconductor packages 1000 may be formed by individualizing the device substrate 100 and upper structure members of the device substrate 100, by using a singulation process, such as a sawing process or a dicing process. Each of the semiconductor packages 1000 may correspond to, for example, an HBM package. Accordingly, each of the semiconductor packages 1000 may include the first semiconductor chip 100c, the plurality of second semiconductor chips 140, the external connection terminal 120, and the sealing material 180.

Although the process of manufacturing an HBM package has been described up to this point, the method of manufacturing a semiconductor package according to the present embodiment is not limited thereto. For example, the method of manufacturing a semiconductor package according to the present embodiment may be applied to all of the methods of manufacturing semiconductor packages which may be manufactured by using the WSS.

FIGS. 3A to 3C are a cross-sectional view and graphs for explaining issues in a method of manufacturing a semiconductor package by using the carrier substrate 200, according to the comparison example of FIG. 1B, respectively. FIG. 3B is a graph related to outgassing of the release layer RL, and FIG. 3C is a graph related to outgassing of the device wafer D-W.

Referring to FIG. 3A, warpages Chip Warp and Wafer Warp may occur in the carrier wafer C-W and core chips C-C, as a result of the TCB process in the assembly process after the thinning process on the device wafer D-W, in the method of manufacturing a semiconductor package according to a comparison example. In addition, as a result of the warpage, peeling occurs at the interface between the device wafer D-W and the release layer RL, and swells and/or cracks may occur in the device wafer D-W or the core chips C-C during the peeling or in the TCB process after the peeling. In FIG. 3A, portion A, in which the peeling occurs easily, is represented by a circular dashed line.

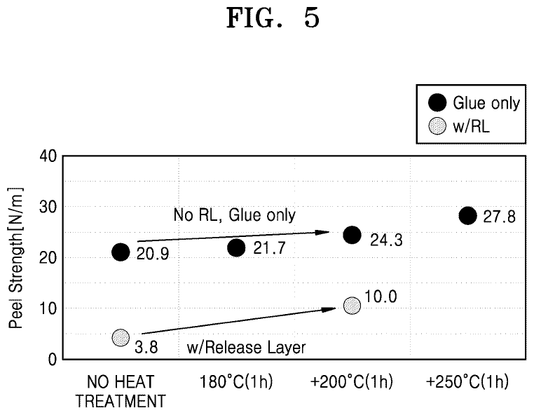

The peeling phenomenon may be due to a low initial peel strength at the release layer RL before the assembly process. Various conditions have been changed to improve an initial peel strength of a release layer and to lower the increase in the peel strength after the thermal process, that is, after the assembly process, but the issue of initial low peel strength has not been solved. For reference, after the thermal process of the assembly process, the peel strength of the release layer RL may rise excessively, and the high peel strength of the release layer RL may cause a crack issue in the device wafer D-W or the carrier wafer C-W in the separation process of the carrier wafer C-W. The issue due to the high peel strength of the release layer RL in the separation process of the carrier wafer C-W is described in more detail with respect to FIGS. 4A through 5.

Due to the TCB process in the assembly process, heat may be transferred to the device wafer D-W, and as a result, the outgassing may occur in a buffer chip of the device wafer D-W and the release layer RL. The outgassing in the buffer chip and the release layer RL may cause, together with the warpage described above, swells and/or cracks in the device wafer D-W or the core chip C-C.

Referring to FIG. 3B, the dashed line in the vertical direction in the graph may represent volatilization temperature Vol, and it may be identified that a mass of the release layer RL rapidly decreases due to outgassing at temperature of the volatilization temperature Vol or higher. In general, the TCB process may be performed at high temperatures, such as about 200° C. to about 300° C., which usually exceed the volatilization temperature Vol. Accordingly, a lot of outgassing may occur in the release layer RL. Various methods, such as reducing the thickness of the release layer RL and changing the material of the release layer RL, are being proposed to reduce the outgassing of the release layer RL.

Referring to FIG. 3C, in the case of the device wafer D-W, moisture absorption may occur naturally and moisture absorbed during the TCB process may be outgassed. In FIG. 3C, it may be identified that the evaporation rate rapidly increases in a shorter time as the temperature increases. Accordingly, to remove moisture absorbed in advance before the assembly process, a dehumidification bake process may be applied.

In the case of the method of manufacturing a semiconductor package according to the present embodiment, because only two glue layers 310 and 320 are used without using the release layer RL, the issues of low peel strength of the initial release layer RL, outgassing from the release layer RL, and high peel strength of the release layer RL during the separation process of the carrier wafer C-W may all be limited and/or solved.

FIGS. 4A and 4B are conceptual diagrams for explaining a process of separating the carrier substrate, in the method of manufacturing a semiconductor package by using the carrier substrate, according to the embodiment of FIG. 1A, and in the method of manufacturing a semiconductor package by using the carrier substrate, according to the comparison example of FIG. 1B, respectively.

Referring to FIG. 4A, in the method of manufacturing a semiconductor package according to the present embodiment, a chemical cleaning method may be used after the mechanical lift-off during the separation process of the carrier substrate 200. FIG. 4A conceptually illustrates a mechanical lift-off process. The coupled structure, on which the assembly process and the sealing material process have been completed, may be fixed to the vacuum chuck 500 via using vacuum absorption. The lower surface of the sealing material of the coupled structure may be seated on the vacuum chuck 500 to be vacuum-adsorbed. On the other hand, a flex plate 600 may be coupled to the upper surface of the carrier substrate 200, and the blade 400 coupled to the flex plate 600 may be inserted into the adhesive layer 300 of the coupled structure. Thereafter, as a flex force F-F is applied to the flex plate 600 in the vertical direction, and in addition, a roller force R-F is applied to the flex plate 600 via a roller 700, the carrier substrate 200 may be separated from the device substrate 100 in a moving direction of the roller 700.

In the separation process of the carrier substrate 200, as illustrated in FIG. 4A, separation may occur at the interface IF between the first glue layer 310 and the second glue layer 320. In other words, in the adhesive layer 300, the adhesive force at the interface IF between the first glue layer 310 and the second glue layer 320 may be the lowest, and accordingly, separation may occur at the interface IF in the separation process of the carrier substrate 200. In addition, due to the low peel strength at the interface IF, the issue of crack occurrence in the carrier substrate 200 or the device substrate 100 may be solved during the separation process of the carrier substrate 200. In addition, because the chemical cleaning process has not yet been performed in FIG. 4A, the first glue layer 310 on the device substrate 100 may be maintained as is.

Referring to FIG. 4B, even in the case of the method of manufacturing a semiconductor package according to the comparison example, the chemical cleaning method may be used after mechanical lift-off in the separation process of the carrier wafer C-W. Accordingly, as described above with reference to FIG. 4A, the mechanical lift-off process may be performed. However, in the case of the method of manufacturing a semiconductor package according to the comparison example, the adhesive layer ADH may include the glue layer GL and the release layer RL. In addition, the separation process of the carrier wafer C-W may include a process after the thermal process caused by the assembly process occurs, and as a result, the peel strength of the release layer RL may be excessively high. Thus, during the separation process of the carrier wafer C-W, cracks or the like may occur in the carrier wafer C-W or the device wafer D-W. For reference, in FIG. 4B, PKG may represent a package including the device wafer and core chips, V-C may represent a vacuum chuck, F-P may represent the flex plate, BL may represent the blade, and RR may represent the roller.

FIG. 5 is a graph illustrating amounts of change in the peel strength, in the method of manufacturing a semiconductor package by using the carrier substrate, according to the embodiment of FIGS. 1A and 1n the method of manufacturing a semiconductor package by using the carrier substrate, according to the comparison example of FIG. 1B. The x-axis may represent the heat treatment temperature for a period of about 1 hour and the y-axis may represent the peel strength. In addition, Glue only may correspond to the method of manufacturing a semiconductor package according to the embodiment, and w/RL may correspond to the method of manufacturing a semiconductor package according to the comparison example.

Referring to FIG. 5, in the case of the method of manufacturing a semiconductor package according to the present embodiment, the adhesive layer 300 may include only the first glue layer 310 and the second glue layer 320, and in addition, the interface IF may be maintained between the first glue layer 310 and the second glue layer 320 based on curing at different temperatures. Accordingly, the increase in the peel strength may be as low as (24.3−20.9)/20.9*100=16% after about 1 hour of heat treatment at about 200° C. compared to a state in which the heat treatment has not been performed.

On the other hand, in the case of the method of manufacturing a semiconductor package according to a comparison example, the adhesive layer ADH may include the release layer RL and the glue layer GL. Accordingly, the increase in the peel strength may be very high as (10.0−3.8)/3.8*100=163% after about 1 hour of heat treatment at about 200° C. compared to a state in which the heat treatment has not been performed. In addition, although not illustrated in the graph, when the adhesive layer ADH is heat treated at about 250° C. or higher for about 1 hour, the peel strength of the adhesive layer ADH may increase rapidly.

On the other hand, the state, in which the heat treatment is not performed, may correspond to an initial state, in which the assembly process has not been performed, and the heat treatment at 200° C. or higher for about 1 hour may correspond to the thermal process of the assembly process. In the state, in which the heat treatment has not been performed, the peel strength of the adhesive layer 300 of the method of manufacturing a semiconductor package according to the embodiment may be about 20.9, and the peel strength of the adhesive layer ADH of the method of manufacturing a semiconductor package according to the comparison example may be about 3.8. Thus, it may be identified that the initial peel strength of the adhesive layer 300 according to the embodiment is (20.9−3.8)/3.8*100=450%, that is higher than the initial peel strength of the adhesive layer 300 according to the comparison example. Thus, the method of manufacturing a semiconductor package according to the embodiment may solve the peeling caused by low peel strength and issues related to the peeling. In addition, in the method of manufacturing a semiconductor package according to the present embodiment, because the adhesive layer 300 including only the first glue layer 310 and the second glue layer 320 has, after the thermal process, a low change in the peel strength, an issue of cracks occurring in the carrier substrate 200 or the device substrate 100 during the separation process of the carrier substrate 200 may be solved.

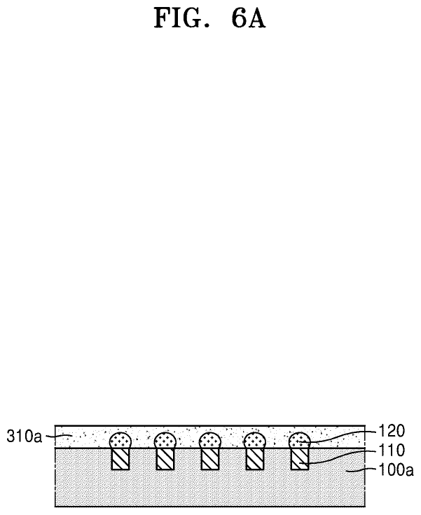

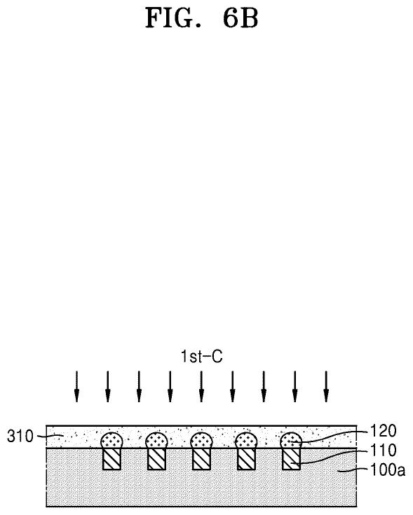

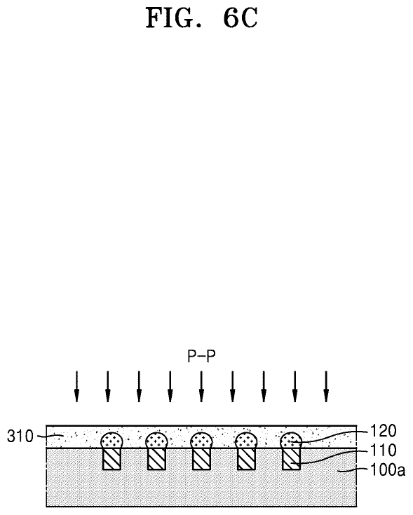

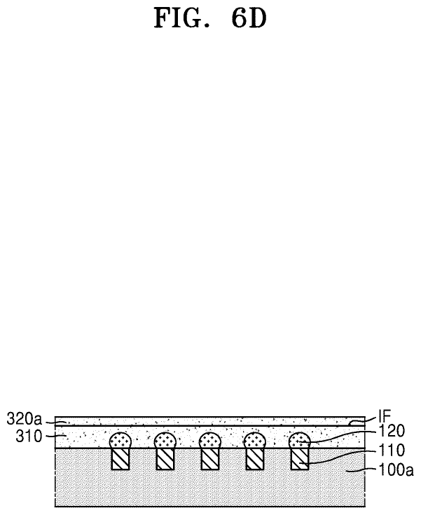

FIGS. 6A through 6D are cross-sectional views illustrating a method of manufacturing a semiconductor package by using the carrier substrate 200, according to embodiments. Duplicate descriptions already given with reference to FIGS. 2A through 2L together, are briefly described or omitted.

Referring to FIG. 6A, in the method of manufacturing a semiconductor package according to the present embodiment, firstly, the first glue layer 310a may be formed on the device substrate 100a. A process of forming the first glue layer 310a on the device substrate 100a may be the same as the process of forming the first glue layer 310a on the device substrate 100a described with reference to FIG. 2A.

Referring to FIG. 6B, after the first glue layer 310a is formed, the first curing 1st-C may be performed. In the method for manufacturing a semiconductor package according to the present embodiment, the temperature of the first curing 1st-C may be about 160° C. to about 180° C. However, the temperature of the first curing 1st-C is not limited thereto. The first glue layer 310, which may be cured by using the first curing 1st-C, may be formed.

Referring to FIG. 6C, after the first curing 1st-C, a surface treatment may be performed on an upper surface of the first glue layer 310. In the method of manufacturing a semiconductor package according to the present embodiment, the surface treatment on the first glue layer 310 may include plasma treatment P-P. By using the plasma treatment P-P, surface bending, that is, surface roughness of the first glue layer 310 may be adjusted. For example, by increasing the surface roughness by using the plasma treatment P-P, the peel strength to the second glue layer 320 may be strengthened in a subsequent process. To the contrary, by reducing the surface roughness by using the plasma treatment P-P, the peel strength to the second glue layer 320 may be reduced.

On the other hand, in the method of manufacturing a semiconductor package of the present embodiment, the surface treatment has been described with the plasma treatment P-P, but the surface treatment is not limited thereto. For example, the surface treatment may include a chemical treatment, a physical treatment, or the like on the upper surface of the first glue layer 310.

Referring to FIG. 6D, after the plasma treatment P-P, the second glue layer 320a may be formed on the first glue layer 310. The second glue layer 320a may also be formed by coating liquid glue on the first glue layer 310 by using a spin coating method. A process of forming the second glue layer 320a may be the same as the process of forming the second glue layer 320a described with reference to FIG. 2C.

On the other hand, in the method of manufacturing a semiconductor package of the present embodiment, the second glue layer 320a may include substantially the same material as the first glue layer 310. For example, like the first glue layer 310a, the second glue layer 320a may also contain a curing agent, and may be hardened by the curing.

After the second glue layer 320a is formed, a semiconductor package may be manufactured by performing the operations in FIGS. 2D through 2L. The method of manufacturing a semiconductor package of the present embodiment may further include a surface treatment, for example, the plasma treatment P-P on the first glue layer 310, and thus, the adhesion force between the first glue layer 310 and the second glue layer 320 may be adjusted. Accordingly, it may be possible to flexibly cope with the initial low adhesion force issue and the excessive increase in the adhesion force after the thermal process, and as a result, a reliable semiconductor package may be manufactured.

While inventive concepts have been particularly shown and described with reference to embodiments thereof, it will be understood that various change in form and details may be made therein without departing from the spirit and scope of the following claims.

What is claimed is:

1. A method of manufacturing a semiconductor package, the method using a carrier substrate, the method comprising:
forming a first glue layer on a device substrate;
forming a second glue layer on the first glue layer;
coupling the device substrate to a carrier substrate by bonding the second glue layer to the carrier substrate;
thinning the device substrate by grinding the device substrate;
stacking first semiconductor chips on the device substrate after the thinning the device substrate; and
separating the carrier substrate from the device substrate at an interface between the first glue layer and the second glue layer.

2. The method of claim 1, further comprising:
after the forming the first glue layer, curing the first glue layer at a first temperature; and
after the coupling of the device substrate to the carrier substrate, curing the second glue layer at a second temperature.

3. The method of claim 2, wherein
the first glue layer and the second glue layer comprise a same material, and
the first temperature and the second temperature are different from each other.

4. The method of claim 2, wherein
the first temperature is 160° C. to 180° C., and
the second temperature is 190° C. to 220° C.

5. The method of claim 2, further comprising,
after the curing the first glue layer at the first temperature, performing a plasma treatment on a surface of the first glue layer.

6. The method of claim 1, wherein there is no release layer between the device substrate and the carrier substrate.

7. The method of claim 1, wherein
the device substrate comprises a plurality of second semiconductor chips, and
the stacking the first semiconductor chips includes forming a stack of the first semiconductor chips on each of the plurality of second semiconductor chips.

8. The method of claim 7, wherein
the stacking the first semiconductor chips includes applying heat and compression to the first semiconductor chips on the device substrate, and
the applying heat and compression increases an adhesion force between the first glue layer and the second glue layer by an amount greater than 0% and less than or equal to 20% compared to the adhesion force between the first glue layer and the second glue layer before the applying the heat and compression.

9. The method of claim 7, further comprising,
after the stacking the first semiconductor chips on the device substrate, sealing the first semiconductor chips on the device substrate with a sealing material.

10. The method of claim 9, further comprising,
after the separating of the carrier substrate, forming semiconductor packages from the device substrate and the first semiconductor chips,
wherein each of the semiconductor packages comprises a corresponding one of the plurality of second semiconductor chips and a corresponding stack of the first semiconductor chips on the corresponding one of the plurality of second semiconductor chips.

11. The method of claim 10, wherein
each of the semiconductor packages comprises a high bandwidth memory (HBM) package,
each of the first semiconductor chips comprises a memory chip, and
each of the plurality of second semiconductor chips comprise a buffer chip.

12. A method of manufacturing a semiconductor package, the method using a carrier substrate, the method comprising:
forming a first glue layer on a device substrate;
curing the first glue layer at a first temperature;
forming a second glue layer on the first glue layer;
coupling the device substrate to the carrier substrate by bonding a carrier substrate to the second glue layer;
curing the second glue layer at a second temperature higher than the first temperature;
thinning the device substrate by grinding the device substrate;
stacking a plurality of first semiconductor chips on the device substrate;
sealing the plurality of first semiconductor chips on the device substrate with a sealing material; and
separating the carrier substrate from the device substrate at an interface between the first glue layer and the second glue layer, wherein
the first glue layer and the second glue layer comprise a same material.

13. The method of claim 12, wherein
the device substrate comprises a plurality of second semiconductor chips, and
the stacking the plurality of first semiconductor chips includes forming a stack of the plurality of first semiconductor chips on each of the plurality of second semiconductor chips.

14. The method of claim 13, further comprising:
after the separating the carrier substrate, forming semiconductor packages from the device substrate and the plurality of first semiconductor chips.

15. The method of claim 14, wherein
each of the semiconductor packages comprises a high bandwidth memory (HBM) package, and
the HBM package comprises a corresponding stack of the plurality of first semiconductor chips on a corresponding one of the plurality of second semiconductor chips, the sealing material to seal the stack of the plurality of first semiconductor chips, and an external connection terminal under a lower surface of the corresponding one of the plurality of second semiconductor chips.

16. A method of manufacturing a semiconductor package, the method using a carrier substrate, and the method comprising:
forming a first glue layer and a second glue layer on a device substrate, the first glue layer and the second glue layer including a same material and being cured at different temperatures to form an interface between the first glue layer and the second glue layer;
coupling the device substrate to the carrier substrate by bonding the carrier substrate to the second glue layer;
thinning the device substrate by grinding the device substrate;
stacking first semiconductor chips on the device substrate; and
separating the carrier substrate from the device substrate at the interface between the first glue layer and the second glue layer.

17. The method of claim 16, wherein the forming the first glue layer and the second glue layer comprises:
forming the first glue layer by coating a glue on the device substrate;
curing the first glue layer at a first temperature;
forming the second glue layer by coating the glue on the first glue layer; and
curing the second glue layer at a second temperature after the coupling the device substrate to the carrier substrate, the second temperature being higher than the first temperature.

18. The method of claim 17, further comprising:
arranging external connection terminals on the device substrate before the forming the first glue layer and the second glue layer on the device substrate, wherein
in the forming the first glue layer, the first glue layer is formed to cover the external connection terminals.

19. The method of claim 16, wherein a release layer is not formed on the device substrate.

20. The method of claim 16, further comprising:
after the stacking the first semiconductor chips, sealing the first semiconductor chips on the device substrate with a sealing material; and
after the separating the device substrate, forming semiconductor packages from the device substrate and the first semiconductor chips, wherein
the device substrate comprises a plurality of second semiconductor chips,
the stacking the first semiconductor chips includes forming a stack of the first semiconductor chips on each of the second semiconductor chips, and
the semiconductor packages each include a corresponding one of the second semiconductor chips.
